(19) United States
(12) Patent Application Publication
(10) Pub. No.: US 2020/0091028 A1
(43) Pub. Date: Mar. 19, 2020

(54) SEMICONDUCTOR PACKAGE USING HIGH POWER AND HIGH FREQUENCY AND METHOD OF MANUFACTURING SAME

(71) Applicant: KOREA ELECTRONICS TECHNOLOGY INSTITUTE, Seongnam-si (KR)

(72) Inventors: Jong Min YOOK, Seongnam-si (KR); Jun Chul KIM, Seongnam-si (KR); Dong Su KIM, Seongnam-si (KR)

(21) Appl. No.: 16/184,191

(22) Filed: Nov. 8, 2018

(30) Foreign Application Priority Data
Sep. 18, 2018 (KR) 10-2018-0111534

(51) Int. Cl. H01L 23/367; H01L 23/00; H01L 23/66; H01L 23/498; H01L 23/532

(52) U.S. Cl. CPC H01L 23/367; H01L 24/32; H01L 24/48; H01L 23/66; H01L 2223/6611; H01L 23/49822; H01L 23/53238; H01L 2924/3511; H01L 24/09

(57) ABSTRACT

Disclosed is a semiconductor package. The semiconductor package includes a semiconductor chip on which an electrode pad is disposed, at least one input/output segment disposed around a side surface of the semiconductor chip to be spaced apart from the semiconductor chip and transmitting an electric signal, and an insulating layer filled between the semiconductor chip and the input/output segment. The insulating layer is provided on the semiconductor chip and the input/output segment to fix and insulate the semiconductor chip and the input/output segment from each other. The semiconductor further includes an electrode pattern provided on the insulating layer and configured to electrically connect the electrode pad of the semiconductor chip and the input/output segment.

### CROSS REFERENCE TO RELATED APPLICATION

The present application claims priority to Korean Patent Application No. 10-2018-0111534, filed Sep. 18, 2018, the entire contents of which is incorporated herein for all purposes by this reference.

### BACKGROUND

### Technical Field

The present disclosure relates to a semiconductor package using high power and high frequency and a method of manufacturing the same.

### Description of Related Technology

With the development of the semiconductor chip manufacturing process and the increase in the operating frequency of the semiconductor chip, a semiconductor package using a conventional wire bonding method has a problem in that electrical characteristics are deteriorated due to generation of parasitic elements. Accordingly, to solve the above problem, an embedded PCB technology and a wafer-level fan-out package technology based on molding are currently being applied to high frequency IC packages, the technologies being capable of realizing a flip-chip mounting structure and minimizing parasitic elements for input/output (I/O) path of electrical signals.

Although the conventional package technologies can reduce the parasitic elements of the input/output (I/O) path of the electric signals, heat is dissipated only through a solder bump formed on a front surface of an IC chip, not through a bottom surface of the IC chip, whereby there is a limit in solving the heat dissipation problem.

Recently, a technology has been developed in which a through conductive via is formed on a package substrate to realize smooth heat dissipation and a bottom mounting structure. However, when the substrate is thick, a diameter of a via hole is increased such that an overall package size is increased, or when the diameter of the via hole is configured to be small, it is difficult to fill with metal, thereby increasing a defect rate.

In addition, when the substrate is thinly processed to facilitate a via processing, additional thinning processing is required. In the case of the thin substrate, wafer warpage occurs after thinning due to the difference in characteristics of each material constituting a multi-layer structure, whereby it is difficult to perform manufacturing processes and package failures occur.

### SUMMARY

Accordingly, the present disclosure has been made keeping in mind the above problems occurring in the related art, and an aspect of the present invention is to provide a semiconductor package for a semiconductor chip operating in a high power and high frequency application environment.

In addition, another aspect of the present invention is to provide a semiconductor package using high power and high frequency, the semiconductor package having a warpage prevention structure to prevent warpage even when using a thin substrate.

Further, still another aspect of the present invention is to provide a semiconductor package using high power and high frequency, which is a bottom mounting type package in which an electrically conductive base substrate is partly used as an electrical signal input/output terminal.

In order to accomplish the above objectives, according to an embodiment of the invention, there is provided a semiconductor package using high power and high frequency, the semiconductor package including: a semiconductor chip on which an electrode pad is disposed; at least one input/output segment disposed around a side surface of the semiconductor chip to be spaced apart from the semiconductor chip and transmitting an electric signal; an insulating layer filled between the semiconductor chip and the input/output segment, and provided on the semiconductor chip and the input/output segment to fix and insulate the semiconductor chip and the input/output segment from each other; and an electrode pattern provided on the insulating layer to electrically connect the electrode pad of the semiconductor chip and the input/output segment.

The input/output segment may be formed using a part of a base substrate.

The base substrate may have stress in a direction opposite to a warping direction.

The base substrate may be formed of two or more layers and has stress in the direction opposite to the warping direction.

The base substrate may include: a first layer; and a second layer provided on one surface of the first layer and generating stress in the direction opposite to the warping direction.

The first layer may be made of copper (Cu) or an alloy containing copper (Cu), and the second layer may be made of a metal selected from the group consisting of nickel (Ni), tungsten (W), and molybdenum (Mo), which have coefficients of thermal expansion lower than that of copper (Cu).

The base substrate may further include a third layer provided on the other surface of the first layer and generating stress in the direction opposite to the warping direction.

The semiconductor package may further include: at least one body segment disposed around the side surface of the semiconductor chip to be spaced apart therefrom and having stress in the direction opposite to the warping direction; and a bottom heat dissipation layer formed on bottom surfaces of the semiconductor chip, the input/output segment, the body segment to dissipate heat generated by the semiconductor chip to the outside.

The semiconductor package may further include at least one frame disposed around the side surface of the semiconductor chip to be spaced apart from the semiconductor chip and the input/output segment, provided from one side toward other side of the semiconductor package, and having stress in a direction opposite to a warping direction.

According to an embodiment of the invention, there is provided a method of manufacturing a semiconductor package using high power and high frequency, the method including: forming an accommodating portion on a base substrate having electrical conductivity in a manner that at least a part of a periphery of the accommodating portion is formed in a serpentine shape to have a protruding portion in which a part of the base substrate protrudes inwardly; mounting a semiconductor chip on which an electrode pad is provided in the accommodating portion; forming a wiring layer in which an insulating layer is filled between the semiconductor chip and the accommodating portion to cover top surfaces of the semiconductor chip and the base substrate, and the protruding portion and the electrode pad of the semiconductor chip are electrically connected to each other; and cutting the base substrate with reference to a point where the protruding portion starts to separate the protruding portion from other portion of the base substrate in order to form an input/output segment.

Before forming the accommodating portion, the method may further include preparing the base substrate to have stress in a direction opposite to a warping direction.

The preparing of the base substrate may include: preparing a first layer; and forming a second layer on the first layer to have stress in the direction opposite to the warping direction.

After forming the wiring layer, the method may further include forming a bottom heat dissipation layer, which is an electrically conductive material and covers bottom surfaces of the base substrate and the semiconductor chip.

The accommodating portion may include: a first accommodating portion on which the semiconductor chip is mounted; a second accommodating portion provided with at least one protruding portion facing the first accommodating portion and spaced apart from the first accommodating portion by a width of a frame; and a third accommodating portion spaced apart from the first accommodating portion and the second accommodating portion by the width of the frame and partitioning a part of the base substrate into a body portion, wherein the accommodating portion may be disposed to define the frame, which is directed from one side to other side of the base substrate, by circumferences of the first accommodating portion, the second accommodating portion, and the third accommodating portion.

The above and other objectives, features, and advantages of the present invention will be more clearly understood from the following detailed description when taken in conjunction with the accompanying drawings.

All terms or words used in the specification and claims have the same meaning as commonly understood by one of ordinary skill in the art to which inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

According to an embodiment of the present invention, it is possible to manufacture a semiconductor package for a semiconductor chip operating in a high power and high frequency application environment.

In addition, according to an embodiment of the present invention, there is provided a semiconductor package using high power and high frequency, the semiconductor package having a warpage prevention structure to be free from warpage even when using a thin substrate.

Further, according to an embodiment of the present invention, there is provided a semiconductor package using high power and high frequency, the semiconductor package using a part of an electrically conductive base substrate as an electrical signal input/output terminal such that a bottom mounting type can be applied and using a bottom heat dissipation layer such that a heat dissipation area of the semiconductor chip is expanded.

### BRIEF DESCRIPTION OF THE DRAWINGS

The above and other objects, features and other advantages of the present invention will be more clearly understood from the following detailed description when taken in conjunction with the accompanying drawings, in which:

FIG. 1 is a plan view illustrating a semiconductor package using high power and high frequency according to an embodiment of the present invention;

FIG. 2 is a bottom view illustrating the semiconductor package using high power and high frequency according to an embodiment of the present invention;

FIG. 3 is a cross-sectional view of FIG. 1 taken along line A-A′;

FIG. 4 is a diagram illustrating a warping direction, which affects the semiconductor package using high power and high frequency according to an embodiment of the present invention;

FIG. 5 is a bottom view illustrating a semiconductor package using high power and high frequency according to an embodiment of the present invention, which further includes a bottom heat dissipation layer;

FIG. 6 is a cross-sectional view of FIG. 5 taken along line A-A′;

FIG. 7 is a cross-sectional view of FIG. 5 taken along line B-B′;

FIG. 8 is a bottom view illustrating a semiconductor package using high power and high frequency according to an embodiment of the present invention, which further includes a bottom heat dissipation layer of an extended form;

FIG. 9 is a cross-sectional view of FIG. 8 taken along line B-B′;

FIG. 10 is a plan view illustrating a semiconductor package using high power and high frequency according to an embodiment of the present invention, which further includes a frame;

FIG. 11 is a cross-sectional view of FIG. 10 taken along line A-A′;

FIG. 12 is a diagram partly illustrating steps of a method of manufacturing a semiconductor package using high power and high frequency according to an embodiment of the present invention;

FIG. 13 is a diagram illustrating a cutting step of the method of manufacturing the semiconductor package using high power and high frequency according to an embodiment of the present invention;

FIG. 14 is a diagram illustrating a bottom heat dissipation layer forming step and a cutting step of the method of manufacturing the semiconductor package using high power and high frequency according to an embodiment of the present invention;

FIG. 15 is a plan view illustrating that a semiconductor chip is mounted on an accommodating portion in the method of manufacturing the semiconductor package using high power and high frequency according to an embodiment of the present invention;

FIGS. 16A and 16B are bottom views respectively illustrating that a bottom heat dissipation layer is formed in the method of manufacturing the semiconductor package using high power and high frequency according to an embodiment of the present invention;

FIG. 17 is a plan view illustrating that the semiconductor chip is mounted on the accommodating portion, which forms a frame structure, in the method of manufacturing the semiconductor package using high power and high frequency according to an embodiment of the present invention.

### DETAILED DESCRIPTION

The above and other objectives, features, and other advantages of the present invention will be more clearly understood from the following detailed description when taken in conjunction with the accompanying drawings. As for reference numerals associated with parts in the drawings, the same reference numerals will refer to the same or like parts through the drawings. It will be understood that, although the terms “one side”, “the other side”, “first”, “second,” etc. may be used herein to describe various elements, these elements should not be limited by these terms. These terms are only used to distinguish one element from another element. Hereinbelow, in the description, details of well-known features and techniques may be omitted to avoid unnecessarily obscuring the presented embodiments.

Hereinbelow, exemplary embodiments of the present invention will be described in detail with reference to the accompanying drawings.

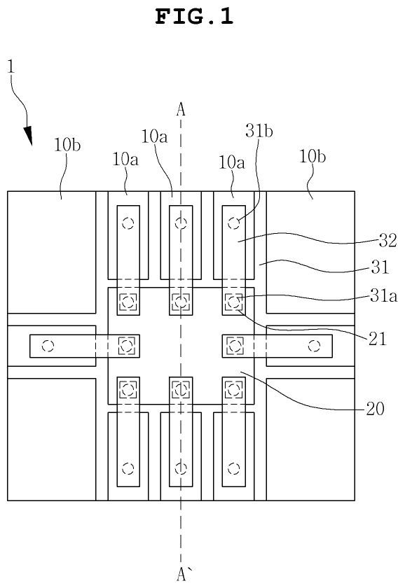

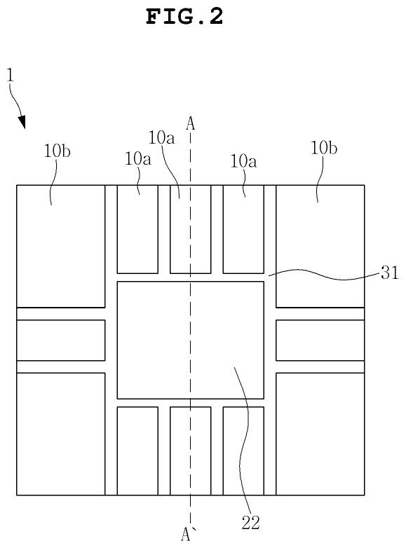

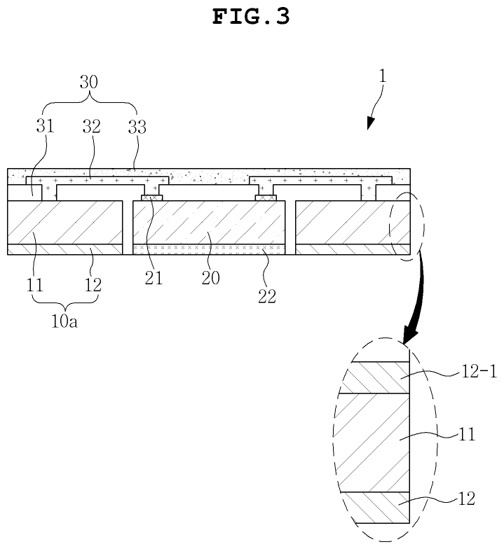

FIG. 1 is a plan view illustrating a semiconductor package 1 using high power and high frequency according to an embodiment of the present invention; FIG. 2 is a bottom view illustrating the semiconductor package 1 using high power and high frequency according to an embodiment of the present invention; and FIG. 3 is a cross-sectional view of FIG. 1 taken along line A-A′.

As shown in FIGS. 1, 2 and 3, the semiconductor package 1 using high power and high frequency includes: a semiconductor chip 20 on which an electrode pad 21 is disposed; at least one input/output segment 10a disposed around a side surface of the semiconductor chip 20 to be spaced apart therefrom and transmitting an electric signal; an insulating layer 31 filled between the semiconductor chip 20 and the input/output segment 10a and provided on the semiconductor chip 20 and the input/output segment 10a to fix and insulate the semiconductor chip 20 and the input/output segment 10a from each other; and an electrode pattern 32 provided on the insulating layer 31 to electrically connect the electrode pad 21 of the semiconductor chip 20 and the input/output segment 10a. In addition, the semiconductor package 1 using high power and high frequency according to an embodiment of the present invention may be a fan-out semiconductor package.

The semiconductor chip 20 has a top surface and a bottom surface opposed to the top surface, and is provided with at least one electrode pad 21 on the top surface. The semiconductor chip 20 may be provided with a bottom electrode pad 22 connected to the ground at the bottom surface thereof. The semiconductor chip 20 may operate at a high operating frequency such as 30 GHz and may be a high power semiconductor. The bottom electrode pad 22 provided on the bottom surface of the semiconductor chip 20 may be connected to an external circuit or a heat sink to effectively dissipate heat generated by the semiconductor chip 20. The bottom electrode pad 22 may be connected to the ground of the external circuit such that the bottom electrode pad 22 is used as the ground of the semiconductor chip 20.

At least one input/output segment 10a is disposed around the side surface of the semiconductor chip 20 to be spaced a constant distance apart therefrom. The number of input/output segments 10a is provided corresponding to the number of the electrode pads 21 of the semiconductor chip 20. The input/output segment 10a may be formed using a part of a base substrate 10 accommodating the semiconductor chip 20, and the base substrate 10 may be formed of a metal having electrical conductivity. For example, the input/output segment 10a may be formed using a part of the base substrate 10, which is formed of a metal such as copper (Cu) and aluminum (Al), and an alloy containing the same.

At least one body segment 10b is disposed around the side surface of the semiconductor chip 20 to be spaced a constant distance apart therefrom. The body segment 10b is disposed to be spaced apart from the input/output segment 10a. The body segment 10b may be formed using a part of the base substrate 10. The body segment 10b is provided in a space in the semiconductor package, where the semiconductor chip 20 and the input/output segment 10a are not disposed, and functions as a body of the semiconductor package. The body segment 10b may be replaced with a wide area input/output segment 10a.

A wiring layer 30 is provided to transmit an electrical signal on the semiconductor chip 20 and the input/output segment 10a. The wiring layer 30 may include the insulating layer 31 and the electrode pattern 32, and further include a protective layer 33.

The insulating layer 31 is filled between the semiconductor chip 20, the input/output segment 10a, and the body segment 10b, and covers top surfaces of the semiconductor chip 20, the input/output segment 10a, and the body segment 10b to fix and support the semiconductor chip 20, the input/output segment 10a, and the body segment 10b. The insulating layer 31 is formed of an electrically insulating material, and fixes and supports the semiconductor chip 20 and the input/output segment 10a. The insulating layer 31 electrically insulates the semiconductor chip 20, the input/output segment 10a, and the body segment 10b from each other. The insulating layer 31 may have a hole-shaped opening. A first opening 31a is provided at the insulating layer 31, which is on the electrode pad 21 of the semiconductor chip 20, to provide a path through which the electrode pattern 32 is connected to the electrode pad 21. A second opening 31b is provided at the insulating layer 31, which is on the input/output segment 10a, to provide a path through which the electrode pattern 32 is connected to the input/output segment 10a. The number of first openings 31a may be provided corresponding to the number of the electrode pads 21 of the semiconductor chip 20. The number of second openings 31b may be provided corresponding to the number of the input/output segments 10a. As shown in FIGS. 1 and 3, the first opening 31a is provided at a portion of the insulating layer 31 where the electrode pad 21 of the semiconductor chip 20 is located, and the second opening 31a is provided at a portion of the insulating layer 31 where the input/output segment 10a is located.

The electrode pattern 32 is provided on the insulating layer 31 to electrically connect the electrode pad 21 of the semiconductor chip 20 and the input/output segment 10a. The electrode patterns 32 may be provided for each input/output segment 10a corresponding to the electrode pad 21. The electrode pattern 32 may be configured to connect one electrode pad 21 and multiple input/output segments 10a, if necessary, and may be configured to connect multiple electrode pads 21 and one input/output segment 10a. An electrical signal output from the electrode pad 21 of the semiconductor chip 20 is transmitted to the input/output segment 10a through the electrode pattern 32. Then, the electrical signal is transmitted from the top surface to the bottom surface of the input/output segment 10a such that the electrical signal is transmitted to the external circuit connected to the bottom surface of the input/output segment 10a.

The protective layer 33 may be formed of the same insulation material as the insulating layer 31. The protective layer 33 may be provided on the insulating layer 31 to cover and protect the electrode pattern 32.

In a semiconductor package in which the semiconductor chip 20 is mounted in an embedded manner, when a through conductive via is formed on a substrate of the semiconductor package for transmission of electric signals or for heat dissipation, a diameter of a via hole is increased such that an overall package size is increased. On the contrary, when the diameter of the via hole is configured to be small, it is difficult to fill the via hole with metal, thereby increasing defect rate.

In contrast, the semiconductor package 1 using high power and high frequency according to an embodiment of the present invention uses the input/output segment 10a, which is formed using a part of the base substrate 10 made of a metal, as an electric signal transmission path extending from the top surface to the bottom surface of the semiconductor package. Accordingly, the semiconductor package 1 using high power and high frequency according to an embodiment of the present invention does not need to form the through conductive via in the semiconductor package. Therefore, there is advantages in that it is possible to miniaturize the semiconductor package and eliminate a possibility that defects may occur in the process of forming the via hole. In addition, because the semiconductor package 1 using high power and high frequency according to an embodiment of the present invention does not use wire bonding method, an influence of parasitic elements is reduced even when the semiconductor package 1 operates at a high frequency.

In addition, the semiconductor package 1 using high power and high frequency according to an embodiment of the present invention may apply a bottom mounting type in which the bottom electrode pad 22 provided on the bottom surface of the semiconductor chip 20 and the bottom surface of the input/output segment 10a directly come into contact with the external circuit or the heat sink. Accordingly, the heat generated by the semiconductor chip 20 is directly dissipated to the outside, thereby improving the heat dissipation performance of the semiconductor package. Therefore, the semiconductor package 1 using high power and high frequency according to an embodiment of the present invention can be used for packaging high power semiconductor chip 20 that generates a lot of heat such as power semiconductors.

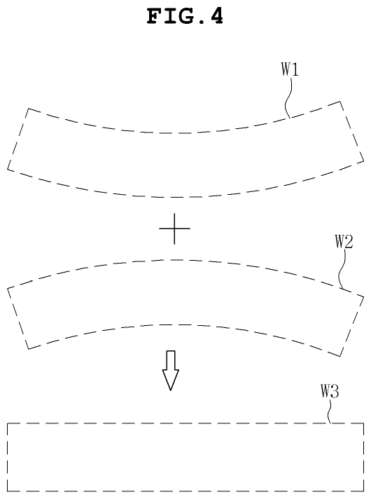

FIG. 4 is a diagram illustrating a warping direction, which affects the semiconductor package 1 using high power and high frequency according to an embodiment of the present invention.

In a general semiconductor package, warpage may occur along a warping direction W1 shown in FIG. 4 due to various factors such as an internal structure, a difference in materials of the internal structure, environmental changes such as temperature in a manufacturing process, and other various causes. The warping direction W1 shown in FIG. 4 is an example that the wiring layer 30 located at an upper portion of the semiconductor package 1 is compressed relative to the base substrate 10 and the semiconductor chip 20 located at a lower portion of the semiconductor package 1, and the base substrate 10 and the semiconductor chip 20 of the lower portion of the semiconductor package 1 are stretched relative to the wiring layer 30 of the upper portion of the semiconductor package 1. Depending on a semiconductor package, warpage may occur in a direction W2 opposite to the warping direction W1 shown in FIG. 4. Such warpage in the semiconductor package causes displacement during the manufacturing process, increases a defect rate of the semiconductor package, and causes physical damage to the semiconductor chip 20.

Referring back to FIG. 3, in the semiconductor package 1 using high power and high frequency according to an embodiment of the present invention, the wiring layer 30 including the insulating layer 31, the electrode pattern 32, and the protective layer 33 is located at the upper portion of the semiconductor package and the input/output segment 10a and the semiconductor chip 20 are located at the lower portion of the semiconductor package. Thus, the upper and lower portions of the semiconductor package are an asymmetric structure. The asymmetric structure may have warpage in the warping direction W1 in an environment where the temperature changes, due to a difference between a coefficient of thermal expansion (CTE) of a material constituting the wiring layer 30 and CTEs of materials of the semiconductor chip 20 and the input/output segment 10a. Alternatively, the asymmetric structure may have warpage in the warping direction W1 due to differences in physical properties other than the difference in CTE, due to causes other than the temperature change.

The input/output segment 10a and the body segment 10b of the semiconductor package 1 using high power and high frequency according to an embodiment of the present invention have stress in the direction W2 opposite to the warping direction W1 as shown in FIG. 4. In other words, when warpage occurs such that the upper portion of the semiconductor package is depressed W1, the input/output segment 10a and the body segment 10b may have stress such that the upper portion of the semiconductor package is prominent W2. Conversely, when warpage occurs such that the upper portion of the semiconductor package is prominent W2, the input/output segment 10a and the body segment 10b may have stress such that the upper portion of the semiconductor package is depressed W1.

The stress of the input/output segment 10a and the body segment 10b acts in the direction W2 opposite to the warping direction W1 occurring in the semiconductor package such warpage of the semiconductor package is prevented as shown in FIG. 4, whereby it is possible to provide the semiconductor package in a flat form W3. That is, the semiconductor package 1 using high power and high frequency according to an embodiment of the present invention prevents the stressed base substrate 10, input/output segment 10a, and body segment 10b against warping in the warping direction W1, although the upper and lower configurations of the semiconductor package are not physically symmetrical.

Since the input/output segment 10a and the body segment 10b are formed by using a part of the base substrate 10, the input/output segment 10a and the body segment 10b having stress may be provided by using the base substrate 10 having stress in the direction W2 opposite to the warping direction W1.

In this description, the expression that the base substrate 10, the input/output segment 10a, or the body segment 10b have stress means a state in which the base substrate 10 has a force to bend in a specific direction, means a state in which the semiconductor package is opposed in the opposite direction W2 against a force bending in the warping direction W1, or means having a structure that can be bent in a specific direction by temperature change.

The base substrate 10 may be formed as a single layer. For example, the base substrate 10 may be made of a single metal such as copper (Cu), tungsten (W), molybdenum (Mo), aluminum (Al), or an alloy of metals. Even when the base substrate 10 is formed as a single layer, the base substrate 10 can be manufactured to have stress in the direction W2 opposite to the warping direction W1 of the semiconductor package.

The base substrate 10 may be formed of two or more layers. For example, the base substrate 10 may include a first layer 11, and a second layer 12 provided on one surface of the first layer 11 and generating stress in the direction W2 opposite to the warping direction W1. The second layer 12 may be provided on a bottom surface or on a top surface of the first layer 11 to generate stress in the direction W2 opposite to the warping direction W1. The first layer 11 and the second layer 12 may be made of a same material or different materials. The first layer 11 may be made of copper (Cu) and the second layer 12 may be made of the same copper (Cu) material as the first layer 11 on one surface of the first layer 11 in a manner that the base substrate 10 has stress in the direction W2 opposite to the warping direction.

Alternatively, the first layer 11 may be made of copper (Cu) or an alloy including copper (Cu) and the second layer 12 provided on the first layer 11 may be formed as a thin film made of a metal selected from the group consisting of nickel (Ni), tungsten (W), molybdenum (Mo), and the like, which have CTEs lower than that of copper (Cu), in a manner that the base substrate 10 has stress in the direction W2 opposite to the warping direction. A direction and a degree of stress of the base substrate 10 can be adjusted by adjusting the thickness of the second layer 12. Further, the base substrate 10 may be formed of multiple layers using multiple materials.

The base substrate 10 may be formed of three or more layers. For example, the second layer 12 may be provided on one surface of the first layer 11 and a third layer 12-1 may be provided on the other surface of the first layer 11, which is opposite to the second layer 12, as shown in the enlarged view of FIG. 3. The first layer 11 may be made of copper (Cu) and the second layer 12 and the third layer 12-1 may be made of a material such as nickel (Ni), tungsten (W), and molybdenum (Mo). The second layer 12 and the third layer 12 may be made of tungsten (W), or the second layer 12 may be made of tungsten (W) and the third layer 12-1 may be made of molybdenum (Mo). A direction and a degree of stress of the base substrate 10 can be adjusted by adjusting the thicknesses of the second layer 12 and the third layer 12-1 individually.

Since the semiconductor package 1 using high power and high frequency according to an embodiment of the present invention includes the input/output segment 10a and the body segment 10b having stress in the opposite direction to the warping direction, it is possible to prevent warpage that may occur due to imbalance of the upper and lower configurations of the semiconductor package. Accordingly, the defect rate of the semiconductor package is reduced. In addition, since the semiconductor package 1 using high power and high frequency according to an embodiment of the present invention prevents warpage without having a physically symmetrical upper and lower configurations of the semiconductor package, it is possible to design the semiconductor package without limitations such as symmetrical configuration.

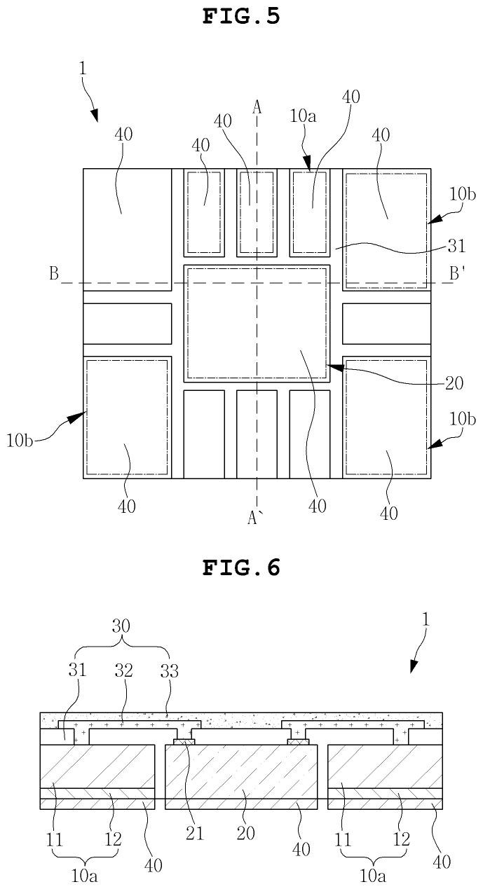

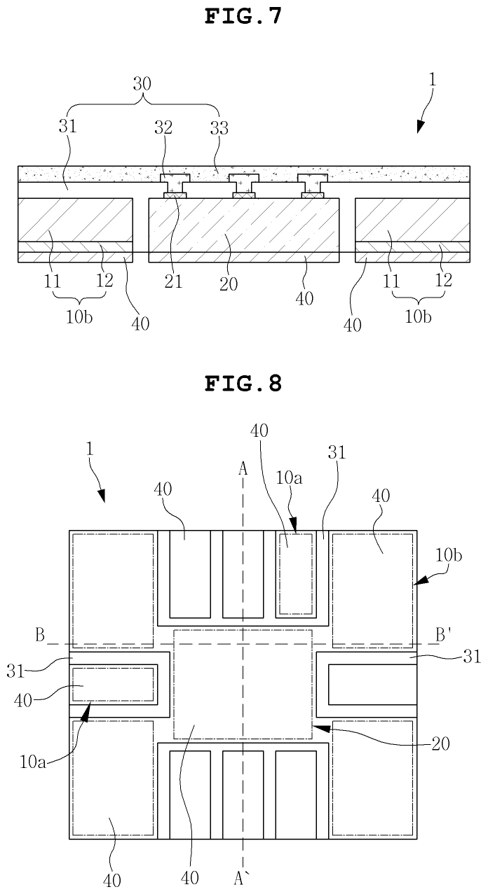

FIG. 5 is a bottom view illustrating a semiconductor package 1 using high power and high frequency according to an embodiment of the present invention, which further includes a bottom heat dissipation layer 40; FIG. 6 is a cross-sectional view of FIG. 5 taken along line A-A′; and FIG. 7 is a cross-sectional view of FIG. 5 taken along line B-B′. In FIG. 5, the semiconductor chip 20, the input/output segment 10a, and the body segment 10b, which are hidden by the bottom heat dissipation layer 40 and invisible, are indicated by chain lines.

The semiconductor package 1 using high power and high frequency according to an embodiment of the present invention may further include the bottom heat dissipation layer 40, which is provided on the bottom surfaces of the semiconductor chip 20, the input/output segment 10a, and the body segment 10b to dissipate heat generated by the semiconductor chip 20 to the outside.

As shown in FIGS. 5, 6 and 7, the bottom heat dissipation layer 40 is not provided on a bottom surface of the insulating layer 31 provided between the semiconductor chip 20, the input/output segment 10a, and the body segments 10b. Thus, the electrical signal transmitted through the input/output segment 10a is not transmitted to the bottom electrode pad 22 and the body segment 10b through the bottom heat dissipation layer 40. In addition, the electric signals flowing through the input/output segment 10a are not mixed through the bottom heat dissipation layer 40.

The bottom heat dissipation layer 40 may be made of a metal having high electrical conductivity and thermal conductivity. For example, the bottom heat dissipation layer 40 may be made of metal such as copper (Cu) and aluminum (Al), or an alloy of metals. The bottom surface of the input/output segment 10a may be electrically connected to the external circuit through the bottom heat dissipation layer 40 having electrical conductivity.

In the case where the bottom electrode pad 22 is present on the bottom surface of the semiconductor chip 20 (refer to FIG. 3), mounting or soldering can be performed on an external circuit board or on a heat sink without having the bottom heat dissipation layer 40.

However, in the case that the bottom electrode pad 22 made of a metal is not provided on the bottom surface of the semiconductor chip 20 (refer to FIGS. 6 and 7), the bottom surface of the semiconductor chip 20 comes into direct contact with the external circuit board or the heat sink when mounting the semiconductor package. Direct soldering between the bottom surface of the semiconductor chip 20 and the external circuit board lowers electrical stability of the semiconductor chip 20. However, not soldering on the bottom surface of the semiconductor chip 20 lowers heat dissipation characteristic due to voids between the bottom surface of the semiconductor chip 20 and the external circuit board.

In order to solve the above problems, in the case that the bottom surface of the semiconductor chip 20 is not covered by the bottom electrode pad 22, the heat dissipation layer 40 may be provided to cover the bottom surface of the semiconductor chip 20. The bottom heat dissipation layer 40 is provided on the bottom surfaces of the semiconductor chip 20, the input/output segment 10a, and the body segment 10b to facilitate surface mounting, soldering, or the like. Further, the bottom heat dissipation layer 40 enhances the adhesion between the bottom surface of the semiconductor chip 20 and the external circuit board or the heat sink, thereby contributing to heat dissipation.

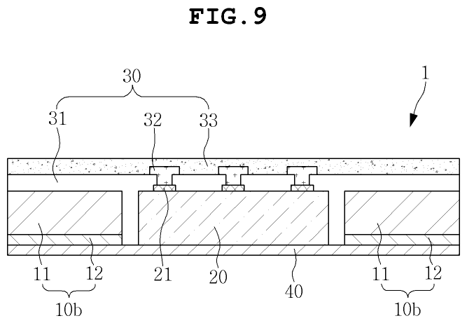

FIG. 8 is a bottom view illustrating a semiconductor package 1 using high power and high frequency according to an embodiment of the present invention, which further includes a bottom heat dissipation layer 40 of an extended form; and FIG. 9 is a cross-sectional view of FIG. 8 taken along line B-B′. In FIG. 8, the semiconductor chip 20, the input/output segment 10a, and the body segment 10b, which are hidden by the bottom heat dissipation layer 40 and invisible, are indicated by chain lines.

As shown in FIGS. 8 and 9, a bottom heat dissipation layer 40 of the semiconductor package 1 using high power and high frequency according to an embodiment of the present invention may be integrally provided on the bottom surfaces of the semiconductor chip 20 and the body segment 10b as the extended body. Here, the bottom heat dissipation layer 40 provided on the bottom surfaces of the semiconductor chip 20 and the body segment 10b and a bottom heat dissipation layer 40 provided on the bottom surface of the input/output segment 10a are configured to be spaced apart from each other as shown in FIG. 6.

The bottom heat dissipation layer 40 provided on the bottom surface of the semiconductor chip 20 receives heat generated from the semiconductor chip 20 and transfer the heat to the bottom heat dissipation layer 40 provided on the bottom surface of the body segment 10b, leading to increase of the heat dissipation area. When reducing an area of the input/output segment 10a and increasing an area of the body segment 10b, an area of the bottom heat dissipation layer 40 provided on the bottom surfaces of the body segment 10b and the semiconductor chip 20 as an integrated body is widened such that the heat dissipation area is expanded.

FIGS. 8 and 9 illustrate the semiconductor chip 20 having no bottom electrode pad 22. However, even when the bottom electrode pad 22 is present on the bottom surface of the semiconductor chip 20 (refer to FIG. 3), providing the bottom heat dissipation layer 40 on the bottom surface of the semiconductor chip 20 (that is, the bottom surface of the bottom electrode pad 22) and the bottom surface of the body segment 10b as an integrated body is effective in increasing of the heat dissipation area.

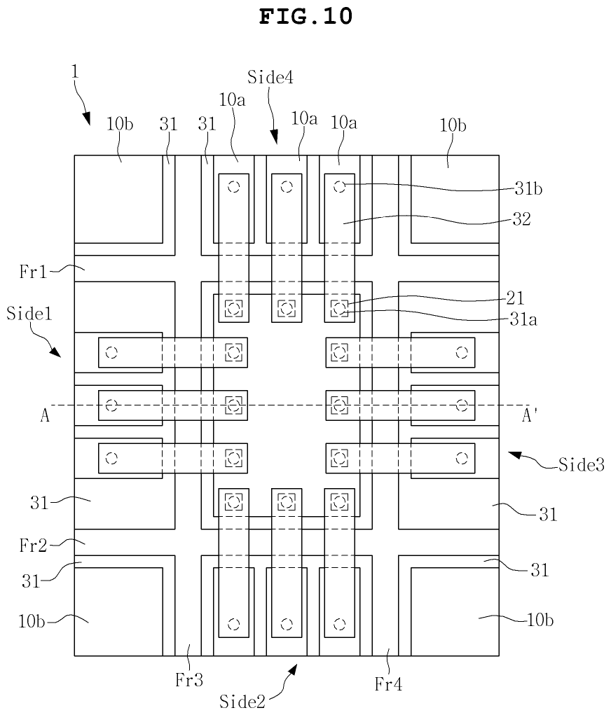

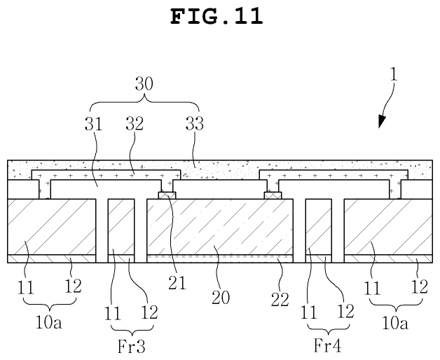

FIG. 10 is a plan view illustrating a semiconductor package 1 using high power and high frequency according to an embodiment of the present invention, which further includes a frame Fr; and FIG. 11 is a cross-sectional view of FIG. 10 taken along line A-A′.

The semiconductor package 1 using high power and high frequency according to an embodiment of the present invention further includes at least one frame Fr, which is disposed around the side surface of the semiconductor chip 20 to be spaced apart from the semiconductor chip 20 and the input/output segment 10a, provided from one side toward other side of the semiconductor package in a first direction, and has stress in a direction opposite to a warping direction.

For example, when the semiconductor package 1 using high power and high frequency has first to fourth sides (Sides 1 to 4), a first frame Fr 1 may be formed straight from the first side (Side 1) toward the third side (Side 3). Alternatively, the first frame Fr 1 may be formed from the first side (Side 1) toward the second side (Side 2). The frame Fr may be not formed straight, but may be formed in a predetermined pattern such as a curve or a mesh.

Since the frame Fr is integrally formed without being disconnected from one side to the other side of the semiconductor package, the stress of the frame Fr affects the entire semiconductor package around a portion where the frame Fr is formed. Therefore, in preventing warpage of the semiconductor package, the effect of the frame Fr preventing warpage is greater than those of the input/output segment 10a and the body segment 10b.

At least one frame Fr may be provided. For example, a first frame Fr1 may be formed from the first side (Side 1) toward the third side (Side 3) and a second frame Fr2 may be formed parallel to the first frame Fr1. Alternatively, another frame Fr may be formed to be inclined at a predetermined angle with respect to the first frame Fr1 (not shown). Alternatively, a third frame Fr3 may be formed from the second side (Side 2) toward the fourth side (Side 4) to be perpendicular to the first frame Fr 1 formed from the first side (Side 1) toward the third side (Side 3).

As shown in FIG. 10, crossing frames (Fr1, Fr2, Fr3, and Fr4) may be integrally formed. For example, a first frame Fr 1 and a second frame Fr2, which are formed from the first side (Side 1) toward the third side (Side 3), and a third frame Fr3 and a fourth frame Fr4, which are formed from the second side (Side 2) toward the fourth side (Side 4) to be perpendicular to the first frame Fr 1, are integrally formed such that a # shape or a mesh shape is provided consequently. Here, the frame Fr is formed to surround the semiconductor chip 20 and extends to the sides of the semiconductor package with the semiconductor chip 20 as a center such that stress can be uniformly applied to the entire semiconductor package. Therefore, the frame Fr can effectively prevent warpage of the semiconductor package.

In case of connecting the electrode pattern 32 to the frame Fr, the frame Fr may be used as the input/output segment 10a.

On the other hand, as shown in FIG. 11, the bottom heat dissipation layer 40 may be formed on a bottom surface of the frame Fr. Providing the bottom heat dissipation layer 40 on the bottom surfaces of the frame Fr and the semiconductor chip 20 as an integrated body is effective in increasing of the heat dissipation area, leading to improving of heat dissipating characteristic.

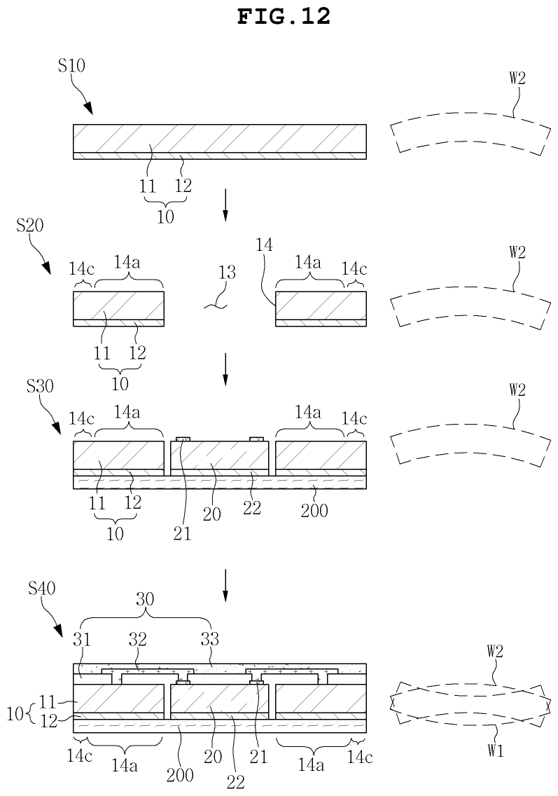

FIG. 12 is a diagram partly illustrating steps of a method of manufacturing a semiconductor package 1 using high power and high frequency according to an embodiment of the present invention. The steps of the method of manufacturing the semiconductor package 1 using high power and high frequency are shown on the left side of FIG. 12, and a warping direction in each step is shown on the right side of FIG. 12.

The method of manufacturing the semiconductor package 1 using high power and high frequency according to an embodiment of the present invention includes: forming an accommodating portion 13 on a base substrate 10 having electrical conductivity in a manner that at least a part of an accommodating portion periphery 14 is formed in a serpentine shape to have a protruding portion 14a in which a part of the base substrate 10 protrudes inwardly (S20); mounting a semiconductor chip 20 on which an electrode pad 21 is provided in the accommodating portion 13 (S30); forming a wiring layer in which an insulating layer 31 is filled between the semiconductor chip 20 and the accommodating portion 13 to cover top surfaces of the semiconductor chip 20 and the base substrate 10, and the protruding portion 14a and the electrode pad 21 of the semiconductor chip 20 are electrically connected to each other (S40); and cutting the base substrate 10 with reference to a point where the protruding portion 14a starts to separate the protruding portion 14a from other portion of the base substrate 10 in order to form an input/output segment 10a (S60).

In addition, before the forming of the accommodating portion 13, the method of manufacturing the semiconductor package 1 using high power and high frequency according to an embodiment of the present invention may further include preparing the base substrate 10 to have stress in a direction opposite to a warping direction.

A semiconductor package is manufactured using a base substrate 10 having no stress to measure a warping degree of the semiconductor package (not shown). For example, when manufacturing a semiconductor package, it is possible to measure a warping degree in accordance with the warping direction W1 in FIG. 2. When the warping direction W1 and the warping degree of the semiconductor package can be predicted in a designing process, it is possible to omit the step of actually manufacturing the semiconductor package and measuring the warping degree.

As shown in FIG. 12, in the preparing of the substrate, the base substrate 10 is prepared to have stress in the direction W2 opposite to the warping direction (refer to W1 of FIG. 2) of the semiconductor package. The base substrate 10 may be formed to have stress in the process of forming the base substrate 10 using a single material or may be formed to have stress in the process of forming the base substrate 10 including two or more layers (first layer 11 and second layer 12). Here, the stress of the base substrate 10 is generated in the direction W2 opposite to the warping direction (refer to W1 of FIG. 2), and the stress of the base substrate 10 is equal to the warping degree of the semiconductor package.

The base substrate 10 may include a first layer 11 and a second layer 12 provided on one surface of the first layer 11. In this case, preparing of the base substrate 10 (S10) may include preparing the first layer 11, and forming the second layer 12 on the first layer 11 to have stress in the direction W2 opposite to the warping direction. When the first layer 11 is made of copper (Cu), the second layer 12 may be made of nickel (Ni). The second layer 12 may be formed on one surface of the first layer 11 by electroplating, sputtering, or the like.

In addition, the base substrate 10 may be formed of three or more layers. For example, the second layer 12 may be provided on one surface of the first layer 11 and a third layer 12-1 may be provided on the other surface of the first layer 11 as shown in the enlarged view of FIG. 3. A warping direction and a warping degree of the base substrate 10 can be adjusted by adjusting the thicknesses of the second layer 12 and the third layer 12-1 individually. The second layer 12 and the third layer 12-1 may be made of a material such as nickel (Ni), tungsten (W), and molybdenum (Mo).

Next, the accommodating portion 13 is formed on the base substrate 10. The accommodating portion 13 is formed in a state where the base substrate 10 having the stress is held flat. At the forming of the accommodating portion 13, only the stress W2 of the base substrate 10 exists.

The accommodating portion 13 may be formed on the base substrate 10 by performing a method such as laser drilling, photolithography, and etching. The accommodating portion 13 may be formed as a hole extending through the top and bottom surfaces of the base substrate 10. At least one accommodating portion 13 may be formed on the base substrate 10, and multiple accommodating portions 13 may be formed on the base substrate 10 to manufacture multiple semiconductor packages at the same time.

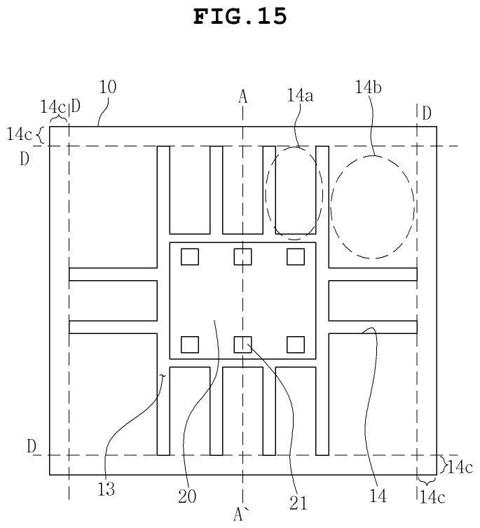

FIG. 15 is a plan view illustrating that the semiconductor chip 20 is mounted on the accommodating portion 13 in the method of manufacturing the semiconductor package using high power and high frequency according to an embodiment of the present invention, and also illustrating a shape of the accommodating portion periphery 14.

As shown in FIG. 15, the accommodating portion 13 is formed to have a size capable of accommodating the semiconductor chip 20 therein corresponding to a size of the semiconductor chip 20. The accommodating portion periphery 14 may be formed to have a pattern. The accommodating portion periphery 14 may have the serpentine shape in which the protruding portion 14a is formed in which a part of the base substrate 10 protrudes inward of the accommodating portion 13. In other words, the accommodating portion periphery 14 may be formed such that the protruding portion 14a, which is a part of the base substrate 10, protrudes inward of the accommodating portion 13.

When the accommodating portion 13 in which the accommodating portion periphery 14 has the serpentine shape is provided on the base substrate 10, a part of the base substrate 10 is referred to as the protruding portion 14a, a body portion 14b, and a fixing portion 14c.

The protruding portion 14a is a portion that becomes the input/output segment 10a (10a of FIG. 1) as the cutting S60 is performed. In a state in which the accommodating portion 13 is formed, the protruding portion 14a is a part of the base substrate 10 and an end of the protruding portion 14a is connected to the fixing portion 14c, which is a part of the base substrate 10. The number of protruding portions 14a may be provided corresponding to the number of the electrode pads 21 of the semiconductor chip 20. The protruding portion 14a may be formed to face the electrode pad 21 of the semiconductor chip 20. Multiple protruding portions 14a may be provided to be spaced a constant distance apart from each other.

The body portion 14b is a portion that becomes the body segment 10b (10b of FIG. 1) as the cutting S60 is performed. The body portion 14b is a part of the base substrate 10, which is not used as the input/output segment 10a.

When the accommodating portion 13 is provided on the base substrate 10, a peripheral portion of the base substrate 10 may be referred to as the fixing portion 14c. The fixing portion 14c is shown to be divided by the cutting line in FIG. 15. When forming the multiple accommodating portions 13 on the base substrate 10 and manufacturing multiple semiconductor packages at the same time, a portion between the accommodating portions 13 in the base substrate 10 can be referred to as the fixing portion 14c. The fixing portion 14c, which is a part of the base substrate 10, is connected to the protruding portion 14a and the body portion 14b formed by the accommodating portion periphery 14, and supports the protruding portion 14a and the body portion 14b.

A detailed pattern of the accommodating portion periphery 14, for example, the number, length, and width of the protruding portion 14a, etc., may be changed depending on a design of the semiconductor chip 20 or the semiconductor package. When the pattern of the accommodating portion periphery 14 has a shape in which a part of the base substrate 10 protrudes inward the accommodating portion 13 and the protruding portion is used as the input/output segment 10a through the cutting step, the pattern is included in the accommodating portion periphery 14 of this embodiment.

Referring to FIG. 12, after the forming of the accommodating portion 13 (S20), the mounting S30 is performed in which a carrier sheet 200 is attached to the bottom surface of the base substrate 10 and the semiconductor chip 20 is mounted on the accommodating portion 13. The semiconductor chip 20 may be mounted in a face-up manner where the top surface of the semiconductor chip 20 on which the electrode pad 21 is disposed faces the upper surface of the base substrate 10.

Next, the wiring layer 30 transmitting an electrical signal to the semiconductor chip 20 and the base substrate 10 is formed (S40). The forming of the wiring layer (S40) may include: forming the insulating layer 31 between the semiconductor chip 20 and an inner surface of the accommodating portion 13 of the base substrate 10 to cover the top surfaces of the semiconductor chip 20 and the base substrate 10; and forming an electrode pattern 32 to electrically connect the electrode pad 21 of the semiconductor chip 20 and the protruding portion 14a of the base substrate.

The insulating layer 31 is filled between the semiconductor chip 20 and the accommodating portion 13 of the base substrate 10 to physically join the semiconductor chip 20, the protruding portion 14a, and the body portion 14b together, and to electrically insulate the semiconductor chip 20, the protruding portion 14a, and the body portion 14b. During forming the insulating layer 31 or after forming the insulating layer 31, an opening is formed in a part of the insulating layer 31 covering the protruding portion 14a and the electrode pad 21 of the semiconductor chip 20 (refer to FIG. 1). A first opening 31a is formed in a part of the insulating layer 31 covering the electrode pad 21 of the semiconductor chip 20, and a second opening 31b is formed in a part of the insulating layer 31 covering the protruding portion 14a. The opening is a space in which the electrode pattern 32 formed on the insulating layer 31 is connected to the electrode pad 21 of the semiconductor chip 20 or to the protruding portion 14a.

Next, at least one electrode pattern 32 electrically connecting the electrode pad 21 of the semiconductor chip 20 and the protruding portion 14a of the base substrate 10 is formed on the insulating layer 31. The number of electrode patterns 32 may be provided corresponding to the number of the electrode pads 21 of the semiconductor chip 20. The electrode pattern 32 may be formed by performing a known method such as pattern plating, electroplating, and etching. The electrode pattern 32 electrically connects the electrode pad 21 of the semiconductor chip 20 and the protruding portion 14a of the base substrate 10 serving as the input/output segment 10a such that a part of the base substrate 10 is used as a transmission path for electrical signals.

Next, the protective layer 33 may be formed on the insulating layer 31 to cover the electrode pattern 32. The protection layer 33 may be formed of a material and a thickness required to insulate and physically protect the semiconductor package from the outside.

After forming the wiring layer 30, warpage occurs in the warping direction W1 due to structural asymmetry of the wiring layer 30 disposed at the top of the semiconductor package and the base substrate 10 and the semiconductor chip 20 disposed at the lower portion of the semiconductor package, and due to other causes. Therefore, after forming the wiring layer 30, the force generating warpage in the warping direction W1 and the stress of the base substrate 10 in the direction W2 opposite to the warping direction W1 coexist on the semiconductor package.

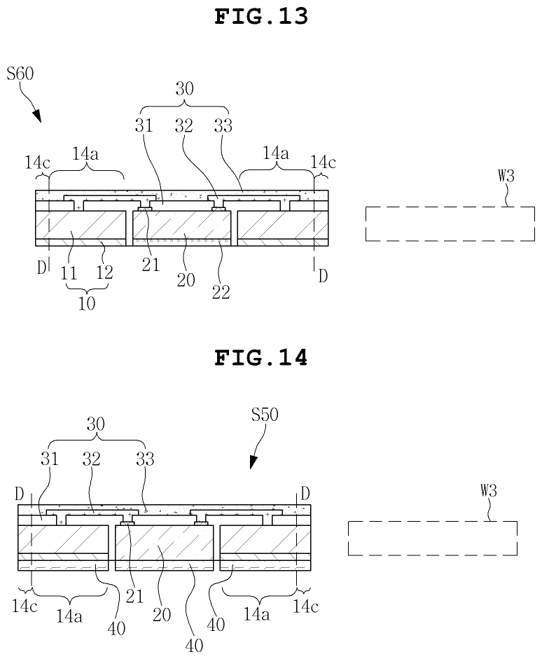

FIG. 13 is a diagram illustrating a cutting step S60 of the method of manufacturing the semiconductor package 1 using high power and high frequency according to an embodiment of the present invention.

After forming the wiring layer 30, the carrier substrate 200 is removed and the cutting S60 is performed with reference to a portion where the protruding portion 14a and the fixing portion 14c of the base substrate 10 are connected to each other such that the input/output segment 10a electrically insulated from the base substrate 10 is formed.

When the portion where the protruding portion 14a of the base substrate 10 and the fixing portion 14c are connected to each other is cut along the cutting line D as shown in FIGS. 13 and 15, the protruding portion 14a is separated from the fixed portion 14c and thus the protruding portion 14a becomes the input/output segment 10a (refer to FIGS. 1 and 3). The fixing portion 14c connecting the multiple protruding portions 14a provided to be separated from each other is separated by cutting such that the multiple protruding portions 14a become multiple input/output segments 10a. The body portion 14b becomes the body segment 10b as the body portion 14b and the fixing portion 14c are also separated along the cutting line D. After cutting, the protruding portions 14a become the input/output segments 10a physically and electrically separated from each other, whereby the input/output segments 10a can be used as a transmission path of electric signals.

The method of manufacturing the semiconductor package 1 using high power and high frequency according to an embodiment of the present invention includes forming a pattern of the accommodating portion 13 in which the protruding portion 14a and the body portion 14b are connected to the fixing portion 14c of the base substrate 10, mounting the semiconductor chip 20, forming the wiring layer 30, and then cutting, such that the protruding portion 14a which is a part of the base substrate 10 is separated. Therefore, since the protruding portion 14a and the body portion 14b are parts of the base substrate 10 coupled to the fixing portion 14c until cutting is performed, it is possible to control in units of the base substrate 10 in the manufacturing process, whereby it is easy to handle. On the contrary, when arranging the input/output segment 10a in a conventional manner in which components are moved around the semiconductor chip 20 one by one, there is a problem that it is difficult to arrange the components in correct positions and the defect rate is high.

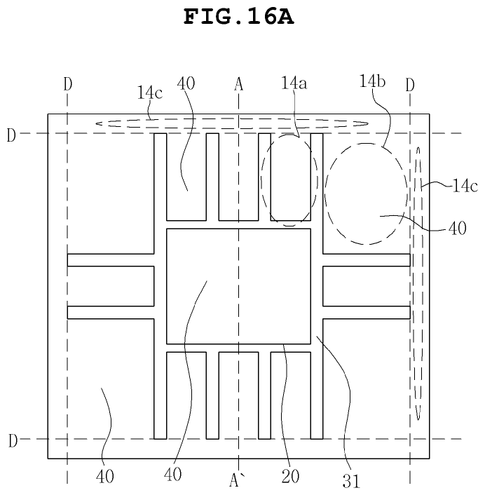

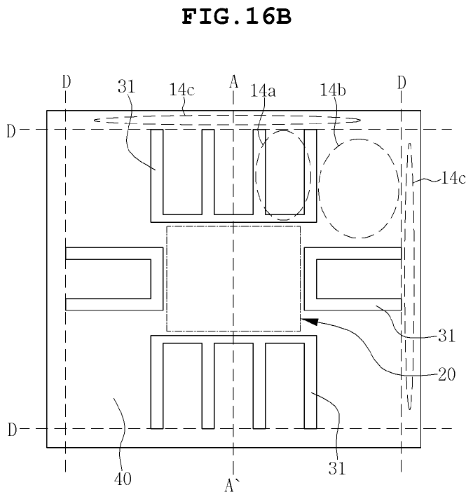

FIGS. 16A and 16B are bottom views respectively illustrating that a bottom heat dissipation layer 40 is formed in the method of manufacturing the semiconductor package 1 using high power and high frequency according to an embodiment of the present invention. The semiconductor chip 20, which is hidden by the bottom heat dissipation layer 40, is indicated by a chain line.

After the forming of the wiring layer S40, the semiconductor package 1 using high power and high frequency according to an embodiment of the present invention may further include forming the bottom heat dissipation layer 40, which is an electrically conductive material and covers bottom surfaces of the base substrate 10 and the semiconductor chip 20 (S50). Cutting S60 may be performed after the forming of the bottom heat dissipation layer 40 (S50).

The forming of the bottom heat dissipation layer 40 (S50) may performed after the forming of the wiring layer S40 and removing of the carrier substrate 200. Alternatively, the forming of the bottom heat dissipation layer 40 (S50) may be performed together with the removing of the carrier substrate 200 and forming of the electrode patterns 32, after the insulating layer 31 is formed. When the electrode pattern 32 and the bottom heat dissipation layer 40 are formed together using a same material, the process can be simplified. The bottom heat dissipation layer 40 may be formed by performing a known method such as pattern plating, electroplating.

As shown in FIG. 16A, the bottom heat dissipation layer 40 may be formed on the bottom surface of the base substrate 10, that is, the bottom surfaces of the protruding portion 14a, the body portion 14b, and the fixing portion 14c in an extended body, and may be formed on the bottom surface of the semiconductor chip 20. Alternatively, as shown in FIG. 16B, the bottom heat dissipation layer 40 may be formed on the bottom surface of the base substrate 10, that is, the bottom surfaces of the protruding portion 14a, the body portion 14b, and the fixing portion 14c, and may be formed on the bottom surfaces of the semiconductor chip 20 and the body portion 14b in an extended body.

After forming the bottom heat dissipation layer 40, the cutting S60 is performed with reference to a portion where the protruding portion 14a and the fixing portion 14c of the base substrate 10 are connected to each other such that the input/output segment 10a electrically insulated from the base substrate 10 is formed.

When cutting a portion where the protruding portion 14a and the fixing portion 14c of the base substrate 10 are connected to each other along the cutting line D, the protruding portion 14a and the body portion 14b are separated from the fixing portion 14c such that the bottom heat dissipation layer 40 is separated. That is, the bottom heat dissipation layer 40 connected along the bottom surface of the base substrate 10 is separated into bottom heat dissipation layers 40 formed on the bottom surfaces of the multiple input/output segments 10a, a bottom heat dissipation layer 40 formed on the bottom surface of the semiconductor chip 20, and a bottom heat dissipation layer 40 formed on the bottom surface of the body segment 10b (refer to FIGS. 16A and 5). When the bottom heat dissipation layer 40 is formed on the bottom surfaces of the semiconductor chip 20 and the body segment 10b as an extended body, the bottom heat dissipation layer 40 formed on the bottom surface of the input/output segment 10a and the bottom heat dissipation layer 40 formed on the bottom surfaces of the semiconductor chip 20 and the body segment 10b are separated from each other (refer to FIGS. 16B and 8).

Hereinafter, a method in which the accommodating portion 13 forms a structure of a frame Fr at the forming of the accommodating portion S20 according to an embodiment of the present invention.

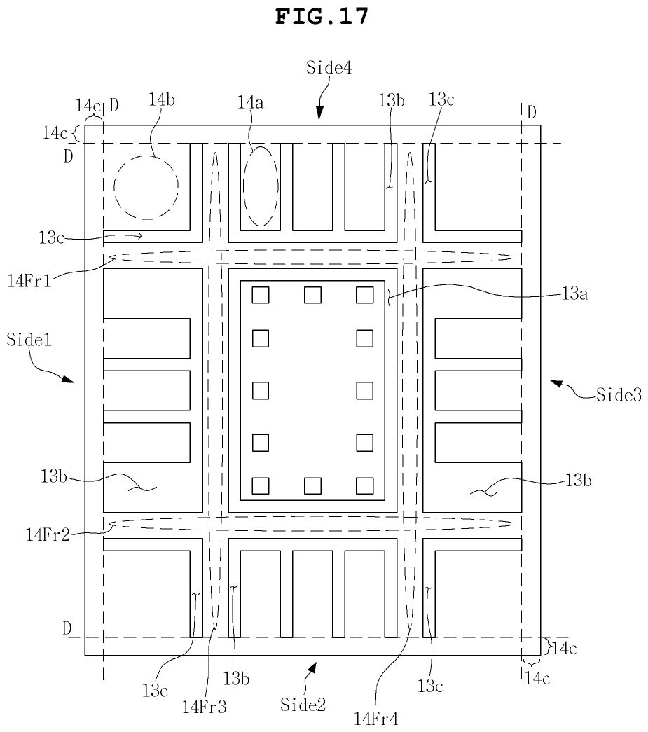

FIG. 17 is a plan view illustrating that the semiconductor chip 20 is mounted on the accommodating portion 13, which forms the structure of the frame Fr, in the method of manufacturing the semiconductor package using high power and high frequency according to an embodiment of the present invention.

As shown in FIG. 17, in the method of manufacturing the semiconductor package 1 using high power and high frequency according to an embodiment of the present invention, the accommodating portion 13 may include: a first accommodating portion 13a on which the semiconductor chip 20 is mounted; a second accommodating portion 13b provided with at least one protruding portion 14a facing the first accommodating portion 13a and spaced apart from the first accommodating portion 13a by a width of the frame Fr; and a third accommodating portion 13c spaced apart from the first accommodating portion 13a and the second accommodating portion 13b by the width of the frame Fr and partitioning a part of the base substrate 10 into the body portion 14b. In addition, the accommodating portion 13 may be disposed to define the frame Fr, which is directed from one side to other side of the base substrate 10, by circumferences of the first accommodating portion 13a, the second accommodating portion 13b, and the third accommodating portion 13c.

The first accommodating portion 13a may be shaped to correspond to the shape of the semiconductor chip 20 in order to accommodate the semiconductor chip 20. The second accommodating portion 13b may be formed to have the protruding portion 14a in which a part of the base substrate 10 protrudes inwardly. The protruding portion 14a may be disposed to face the semiconductor chip 20. The second accommodating portion 13b is provided at a position spaced apart from the first accommodating portion 13a by the width of the frame Fr. The second accommodating portion 13b may be formed in a U shape or an E shape. The third accommodating portion 13c may be formed in an L shape to separate a frame portion 14Fr from the body portion 14b.

One second accommodating portion 13b may be formed for each of the first to fourth sides (Sides 1 to 4) about the first accommodating portion 13a, and third accommodating portions 13c are formed between second accommodating portions 13b such that a # shaped frame portion 14Fr is formed between circumferences of the first accommodating portion 13a, the second accommodating portions 13b, and the third accommodating portions 13c.

For example, as shown in FIG. 17, first and second frame portions 14Fr1 and 14Fr2, which are formed from the first side (Side 1) toward the third side (Side 3), and third and fourth frame portions 14Fr3 and 14Fr4, which are formed from the second side (Side 2) toward the fourth side (Side 4) to be perpendicular to the first frame portion 14Fr1, are integrally formed by the circumferences of the first accommodating portion 13a, the second accommodating portions 13b, and the third accommodating portions 13c.

The frame portion 14Fr is provided as a part of the base substrate 10. In order to treat the frame portion 14Fr, the protruding portion 14a, and the body portion 14b as a unit of the base substrate 10 in the manufacturing process by fixing the frame portion 14Fr, the protruding portion 14a, and the body portion 14b to the fixing portion 14c of the base substrate 10, a part of the base substrate 10 is defined as the frame portion 14Fr by the multiple accommodating portions 13.

FIG. 17 illustrates that the semiconductor chip 20 is mounted on only the first accommodating portion 13, but the present invention is not limited thereto. In order to mount multiple semiconductor chips 20 in one semiconductor package, multiple first receiving portions 13 may be formed, or the second accommodating portion 13 may be widely formed such that the semiconductor chip 20 is mounted on the second accommodating portion 13.

According to an embodiment of the present invention, it is possible to manufacture the semiconductor package 1 for a semiconductor chip operating in a high power and high frequency application environment.

In addition, according to an embodiment of the present invention, it is possible to transmit an electric signal from the upper surface to the lower surface of the semiconductor package by using the input/output segment 10a formed using a part of the base substrate 10, without having a conductive via extending through the semiconductor package. Since there is no need to have a conductive via, the process is simplified, and cost and defect rate is reduced.

In addition, according to an embodiment of the present invention, there is provided the semiconductor package 1 using high power and high frequency, the semiconductor package 1 having a warpage prevention structure to be free from warpage even when using a thin substrate.

In addition, according to an embodiment of the present invention, there is provided the semiconductor package 1 effectively dissipating heat generated during operation of the semiconductor chip 20 in a high-power environment, and transmitting electric signals without distortion, which are transmitted to and received from the outside of the semiconductor chip 20 having a high operating frequency.

Further, according to an embodiment of the present invention, there is provided the semiconductor package 1 using high power and high frequency, the semiconductor package 1 using a part of an electrically conductive base substrate 10 as an electrical signal input/output terminal such that a bottom mounting type can be applied and using the bottom heat dissipation layer 40 such that a heat dissipation area of the semiconductor chip 20 is expanded.

Although certain embodiments of the present invention have been disclosed for illustrative purposes, those skilled in the art will appreciate that various modifications, additions and substitutions are possible, without departing from the scope and spirit of the invention as disclosed in the accompanying claims. It is thus well known to those skilled in that art that the present invention is not limited to the embodiment disclosed in the detailed description.

The scope of the present invention is defined by the accompanying claims rather than the description, which is presented above. Moreover, the present invention is intended to cover not only the exemplary embodiments, but also various alternatives, modifications, equivalents and other embodiments that may be included within the spirit and scope of the present invention as defined by the appended claims.

What is claimed is:

1. A semiconductor package using high power and high frequency, the semiconductor package comprising:
a semiconductor chip on which an electrode pad is disposed;
at least one input/output segment disposed around a side surface of the semiconductor chip to be spaced apart from the semiconductor chip and configured to transmit an electric signal;
an insulating layer filled between the semiconductor chip and the input/output segment, and provided on the semiconductor chip and the input/output segment to fix and insulate the semiconductor chip and the input/output segment from each other; and
an electrode pattern provided on the insulating layer to electrically connect the electrode pad of the semiconductor chip and the input/output segment.

2. The semiconductor package of claim 1, wherein the input/output segment is formed using a part of a base substrate.

3. The semiconductor package of claim 2, wherein the base substrate has stress in a direction opposite to a warping direction.

4. The semiconductor package of claim 3, wherein the base substrate is formed of two or more layers and has stress in the direction opposite to the warping direction.

5. The semiconductor package of claim 4, wherein the base substrate includes:
a first layer; and
a second layer provided on one surface of the first layer and configured to generate stress in the direction opposite to the warping direction.

6. The semiconductor package of claim 5, wherein the first layer is made of copper (Cu) or an alloy containing copper (Cu), and
wherein the second layer is made of a metal selected from the group consisting of nickel (Ni), tungsten (W), and molybdenum (Mo), which have coefficients of thermal expansion lower than that of copper (Cu).

7. The semiconductor package of claim 5, wherein the base substrate further includes a third layer provided on the other surface of the first layer and generating stress in the direction opposite to the warping direction.

8. The semiconductor package of claim 3, further comprising:
at least one body segment disposed around the side surface of the semiconductor chip to be spaced apart therefrom and having stress in the direction opposite to the warping direction; and
a bottom heat dissipation layer formed on bottom surfaces of the semiconductor chip, the input/output segment, the body segment to dissipate heat generated by the semiconductor chip to the outside.

9. The semiconductor package of claim 1, further comprising:
at least one frame disposed around the side surface of the semiconductor chip to be spaced apart from the semiconductor chip and the input/output segment, and provided from one side toward other side of the semiconductor package,
wherein the frame has stress in a direction opposite to a warping direction.

10. A method of manufacturing a semiconductor package using high power and high frequency, the method comprising:
forming an accommodating portion on a base substrate having electrical conductivity in a manner that at least a part of a periphery of the accommodating portion is formed in a serpentine shape to have a protruding portion in which a part of the base substrate protrudes inwardly;
mounting a semiconductor chip on which an electrode pad is provided in the accommodating portion;
forming a wiring layer in which an insulating layer is filled between the semiconductor chip and the accommodating portion to cover top surfaces of the semiconductor chip and the base substrate, and the protruding portion and the electrode pad of the semiconductor chip are electrically connected to each other; and
cutting the base substrate with reference to a point where the protruding portion starts to separate the protruding portion from other portion of the base substrate in order to form an input/output segment.

11. The method of claim 10, further comprising:
before forming the accommodating portion, preparing the base substrate to have stress in a direction opposite to a warping direction.

12. The method of claim 11, wherein the preparing of the base substrate includes:
preparing a first layer; and
forming a second layer on the first layer to have stress in the direction opposite to the warping direction.

13. The method of claim 10, further comprising:
after forming the wiring layer, forming a bottom heat dissipation layer, which is an electrically conductive material and covers bottom surfaces of the base substrate and the semiconductor chip.

14. The method of claim 10, wherein the accommodating portion includes:
a first accommodating portion on which the semiconductor chip is mounted;
a second accommodating portion provided with at least one protruding portion facing the first accommodating portion and spaced apart from the first accommodating portion by a width of a frame; and
a third accommodating portion spaced apart from the first accommodating portion and the second accommodating portion by the width of the frame and partitioning a part of the base substrate into a body portion,
wherein the accommodating portion is disposed to define the frame, which is directed from one side to other side of the base substrate, by circumferences of the first accommodating portion, the second accommodating portion, and the third accommodating portion.
